(19) United States
(12) Patent Application Publication
(10) Pub. No.: US 2003/0094688 A1
(43) Pub. Date: May 22, 2003

(54) Method and apparatus for packaging photodetectors

(76) Inventors: Kirit S. Dharia, Thousand Oaks, CA (US); Robert Franks I, Thousand Oaks, CA (US); Ivair Gontijo, Los Angeles, CA (US); Gary Lee Gutierrez, Newbury Park, CA (US); Dino Mensa, Ventura, CA (US); M.P. Ramachandra Panicker, Camarillo, CA (US); Yet Zen Liu, Westlake Village, CA (US); Ruai Yu, Newbury Park, CA (US)

Correspondence Address: KLEIN, O'NEILL & SINGH, 2 PARK PLAZE, SUITE 510, IRVINE, CA, 92614, US

(21) Appl. No.: 09/991,290

(22) Filed: Oct. 19, 2001

(51) Int. Cl. H01L 23/053

(52) U.S. Cl. 257/701

(57) ABSTRACT

A method and system for photodetector packaging system is provided with a insulating substrate having a shoulder section and a wire bond is used for coupling the photodetector to the insulating substrate at the shoulder section. The system includes an optical fiber that directs incident light directly to the photodetector. Also provided is a method and system for packaging photodetectors with a insulating substrate using conducting vias and a wire bond to couple the photodetector to the insulating substrate. The system includes conducting tabs that are coupled to the conducting vias. The metal tabs are coupled with a transimpedance amplifier by wire bonds and the transimpedance amplifier is coupled to a limiting amplifier by wire bonds.

### BACKGROUND OF THE INVENTION

1. Field of the Invention

The present invention relates to semiconductor photodetectors and, more particularly to packaging photodetectors.

2. Background

Semiconductor photodetectors (hereinafter referred as “photodetectors” or “photodetector”) are extensively used in high bandwidth fiber optics networks. FIG. 1A shows a top level block diagram of a typical fiber optics network 100, which includes a transmitter 100A that receives an electrical input (not shown) and converts it to an optical output 100B using a laser diode (not shown). Optical signal 100B is transmitted via optical fiber (not shown) and is received by optical amplifier 100C. Optical amplifier 100C amplifies optical signal 100B and the amplified signal 100D is transmitted to photodetector 100F, via filter 100E.

FIG. 1B shows a cross-sectional view of a typical photodetector 100F used in network 100. Turning in detail to FIG. 1B, a laminated structure is sequentially formed by a n-type cladding layer 104, an absorption layer 103, a p-type cladding layer 102 and an ohmic contact layer 101, on a semiconductor substrate 105. Electrodes (not shown) are mounted on ohmic contact layer 101 and on the back surface of layer 105. If a reverse voltage is applied between layers 102 and 104, incident light (not shown) guided to absorption layer 103 is converted into a photoelectric signal.

Typically, photodetectors detect light when an absorption layer absorbs incident light from optical fiber. The absorbed photons create primary electron-hole pairs and generate electric current. The photodetector is generally connected to a transimpedance amplifier that receives the output current from the photodetector and converts it into voltage. The transimpedance amplifier is connected to a limiting amplifier that controls the voltage produced by transimpedance amplifier.

Photodetectors used in high bandwidth fiber optics networks must operate efficiently at high frequencies. For example, a fiber optics network under the Synchronous Optical Network (“SONET”) standard requires a 10 gigabits per second (Gbps) data transfer rate, and the photodetector must operate at a frequency range of approximately 10-15 GHz. For a fiber optics network operating at a data rate of 40 Gbps (according to SONET standard OC-768) the photodetector must operate at approximately 40-70 GHz. Such high data rates require the photodetector to be connected to the transimpedance amplifier and the other components in the fiber network so that there is minimum loss in signal transmission, which otherwise could result in signal distortion leading to errors in data transmission.

Traditionally photodetectors have been packaged with glass-to-metal feed through to handle electrical signals. However, that reduces photodetector performance to 5-6 GHz, which is unacceptable at the foregoing high data rates.

Other techniques, as discussed below, use unpackaged photodetectors but require cumbersome alignment and long wire bond connectors that increase inductance and hence negatively affect the performance of the photodetector.

FIG. 2 shows a conventional packaging technique with a cross-sectional view of a receiver module 200 having photodetector 206. Optical fiber 202 covered by fiber cover 203 enters a sealing ring (or wall) 204. The edge 202A of optical fiber 202 is chamfered such that input light 202B is reflected off edge 202A and enters photodetector 206.

Photodetector 206 is connected to transimpedance amplifier 207 via wire bond 209. Transimpedance amplifier 207 is connected to limiting amplifier 208 via wire bond 210, and limiting amplifier 208 is connected to electrical output 212 via wire bond 211. Photodetector 206, transimpedance amplifier 207 and limiting amplifier 208 are all placed on submount 205, which is mounted on base 201.

One disadvantage of the foregoing technique is that photodetector 206 is mounted parallel to optical fiber 202 axis and hence cumbersome alignment and processing is required to direct incident light 202B to photodetector 206 after creating chamfer 202A.

The foregoing optical coupling system is inefficient, and adversely affects the responsiveness of the photodetector.

Another disadvantage of the present invention is that wire bond 209 is long which increases the overall inductance and hence reduces the performance of photodetector 206.

Therefore, there is a need for a method and apparatus for improving the packaging of photodetectors with improved optical coupling efficiency, without cumbersome alignment and long wire bonds.

### SUMMARY OF THE INVENTION

There is provided in accordance with one aspect of the present invention a photodetector packaging system, which includes an insulating substrate with a conducting shoulder section; and a wire bond for connecting the photodetector to the insulating substrate. The system also includes an optical fiber with an unchamfered or cleaved edge that directs incident light directly to the photodetector, increasing the optical coupling efficiency.

In another aspect of the present invention, a method for packaging a photodetector is provided. The method includes mounting the photodetector on an insulating substrate with a shoulder section; and coupling the photodetector to the insulating substrate shoulder section with one or more wire bonds. The photodetector mounted on the insulating substrate is aligned with a cleaved optical fiber to directly receive incident light.

In yet another aspect, the present invention provides a system for packaging photodetectors with an insulating substrate having conducting vias; and a wire bond that couples the photodetector to the insulating substrate. The system includes plural conducting tabs coupled to the conducting vias. The conducting tabs are coupled with a transimpedance amplifier by wire bonds and the transimpedance amplifier is coupled to a limiting amplifier by wire bonds, and the limiting amplifier is coupled to the electrical outputs.

In yet another aspect, the present invention provides a method for packaging photodetectors, by coupling the photodetector to an insulating substrate using conducting vias; wherein the photodetector is coupled to plural conducting metal tabs on the opposite side of the insulating substrate by plural conducting vias that are directly connected to the metal tabs, and the metal tabs are coupled to a transimpedance amplifier, which in turn is coupled to a limiting amplifier.

In yet another aspect of the present invention, because the metal tabs and vias are used to couple the photodetector to an insulating substrate and to the transimpedance amplifier, the overall wire bond length is reduced, which reduces overall inductance and improves photodetector responsiveness.

In accordance with another aspect of the present invention, a photodetector is coupled to a shoulder section of a substrate and is mounted in such a manner that input optical light enters the photodetector directly without being reflected off a reflecting surface in the optical fiber.

This brief summary has been provided so that the nature of the invention may be understood quickly. A more complete understanding of the invention can be obtained by reference to the following detailed description of the preferred embodiments thereof in connection with the attached drawings.

### BRIEF DESCRIPTION OF THE DRAWINGS

FIG. 1A described above, is an illustration of a block diagram of a typical fiber optics network.

FIG. 1B described above, is an illustration of a cross-sectional view of a typical photodetector.

FIG. 2 described above, is a cross-sectional view of a conventional receiver assembly showing an unpackaged photodetector.

FIG. 3A is a schematic illustration of a receiver packaging a photodetector according to an aspect of the present invention.

FIG. 3B is a front elevation of the photodetector assembly with an insulating substrate as shown in FIG. 3A.

FIG. 3C is the side view of the photodetector assembly of FIG. 3A.

FIG. 3D is a cross-sectional view of a receiver module using the photodetector assembly of FIG. 3C.

FIG. 4A shows an exploded view of the photodetector packaging components, according to an aspect of the present invention.

FIG. 4B is the front view of the photodetector coupled to an insulating substrate in FIG. 4A.

FIG. 4C is the end view of the photodetector coupled to an insulating substrate with conducting vias in FIG. 4A.

FIG. 4D is the cross-sectional view of a receiver module using the FIG. 4C photodetector assembly.

FIG. 4E is the exploded view of the photodetector packaging elements with conducting vias, according to an aspect of the present invention.

FIG. 4F is a schematic illustration of a photodetector assembly with conducting vias, according to an aspect of the present invention.

FIG. 5 is a perspective view of a receiving package, according to an aspect of the present invention.

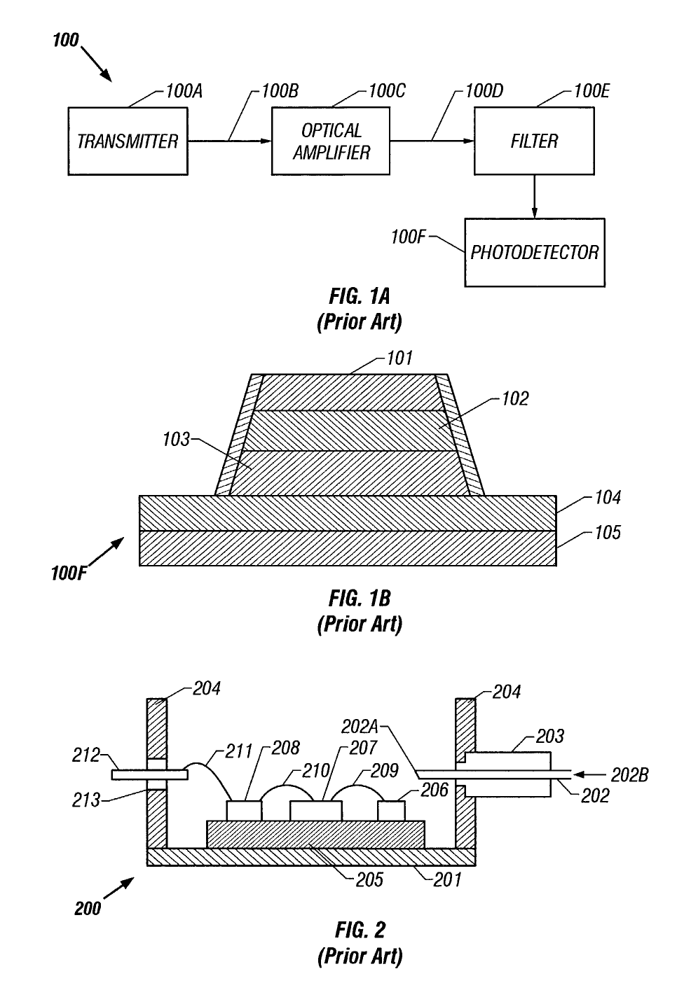

Features appearing in multiple figures with the same reference numeral are the same unless otherwise indicated.

### DETAILED DESCRIPTION

In one aspect of the present invention a packaging technique is provided such that the photodetector is connected to plural conducting vias in an insulating substrate and is mounted in such a manner that input optical light enters the photodetector directly without being reflected off a chamfered edge in the optical fiber.

In another aspect of the present invention a packaging technique is provided such that the photodetector is connected to a shoulder section of a substrate and is mounted in such a manner that input optical light enters the photodetector directly without being reflected off a chamfered edge in the optical fiber.

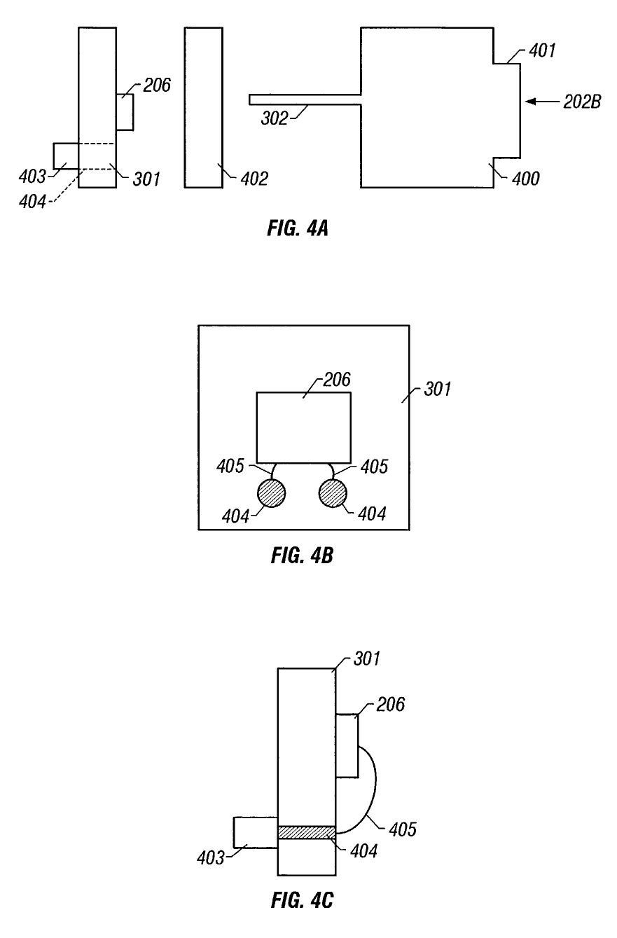

Referring now to FIG. 3A is substrate 301 with shoulder section 300. Photodetector 206 is aligned with respect to optical fiber 302 such that input light 202B enters the photodetector 206 directly. Details of photodetector 206, substrate 301 and shoulder section 300 are provided in FIGS. 3B and 3C.

Turning in detail to FIG. 3B, is photodetector 206 coupled to substrate 301. Photodetector 206 is coupled to substrate 301 at shoulder section 300 via wire bonds 303 and 304. FIG. 3C is the end view of FIG. 3B assembly with photodetector 206 coupled to shoulder section 300 via wire bonds 303 and 304.

Referring now to FIG. 3D, is the photodetector assembly of FIG. 3B used in photodetector receiving module 300A. Input light 202B enters optical fiber 302, which passes through seal ring 204 and is covered by jacket 203. Optical fiber 302 is aligned with respect to photodetector 206 such that input light 202B enters photodetector 206 directly. Wire bond 303 connects photodetector 206 to shoulder section 300, which in turn is connected to transimpedance amplifier 207 via wire bond 305. Transimpedance amplifier 207 is coupled to limiting amplifier 208 by wire bond 305A, and limiting amplifier 208 is coupled to electrical output 212 via wire bond 306.

In one aspect of the present invention, as discussed above, input light 202B directly enters photodetector 206 and no chamfers are required on optical fiber 302 to direct input light.

In yet another aspect of the present invention, a system is provided such that metal tabs and conducting vias are used to couple a photodetector to a conducting substrate and the transimpedance amplifier. Overall wire bond length is reduced which reduces overall inductance and improves photodetector efficiency.

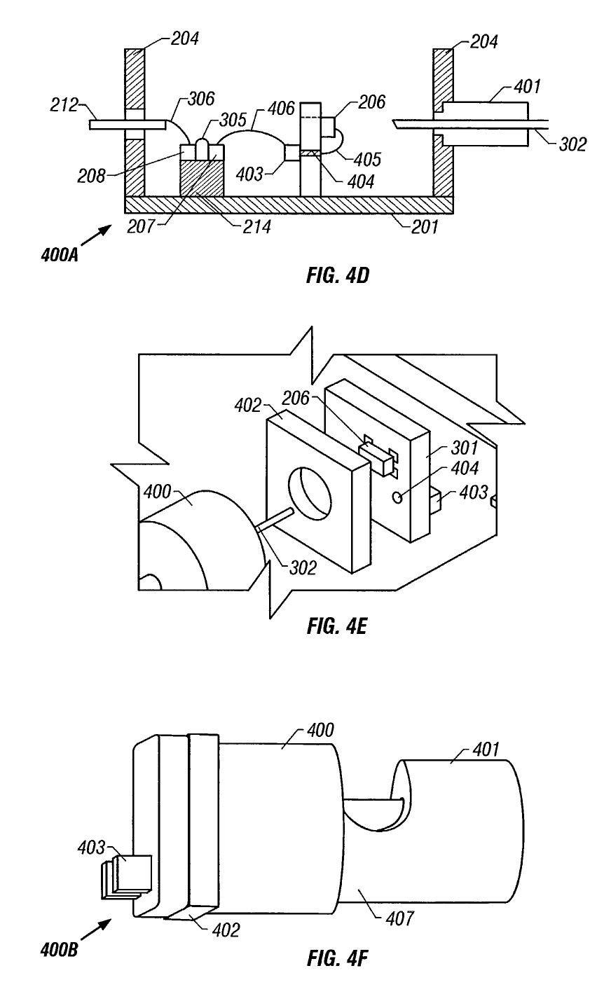

Referring now to the exploded view of FIG. 4A is optical fiber 302 covered by jacket 401 in an optical fiber pipe 400. Photodetector 206 is mounted on insulating substrate 301 and is coupled to conductive metal tabs 403 by conducting vias 404. Metal tabs 403 are coupled to a transimpedance amplifier as discussed below. Insulating substrate 301 may include ceramic materials such as Alumina, Aluminum Nitride, Beryllium Oxide, metals and plastics. It is noteworthy that the invention is not limited to any particular composition of insulating substrate 301.

A spacer 402 is used to align optical fiber 302 with respect to photodetector 206 so that input light 202B enters photodetector 206 directly. Spacer 402 may be plastic, ceramic or, metal, and is coupled to insulating substrate 301 by epoxy, solder, brazing or other material.

Referring now to the top view of FIG. 4B, is insulating substrate 301 with conducting vias 404 that couple insulating substrate 301 with photodetector 206 by wire bond 405. Conducting vias 404 may use pure metal alloys, composite material or other similar material. It is noteworthy that conducting vias 404 do not have to go through insulating substrate 301; alternatively, conducting vias 404 may be replaced with conducting traces around the perimeter of substrate 301, similar to the conducting shoulder 300.

FIG. 4C (the end view of FIG. 4B) shows photodetector 206 coupled to substrate 301 through vias 404 and wire bond 405. Metal tab 403 is coupled to substrate 301 at vias 404. Metal tab 403 in turn is coupled to a transimpedance amplifier, as discussed below. Conducting vias 404 in insulating substrate 301 provides a short path from one side to the other side of insulating substrate 301.

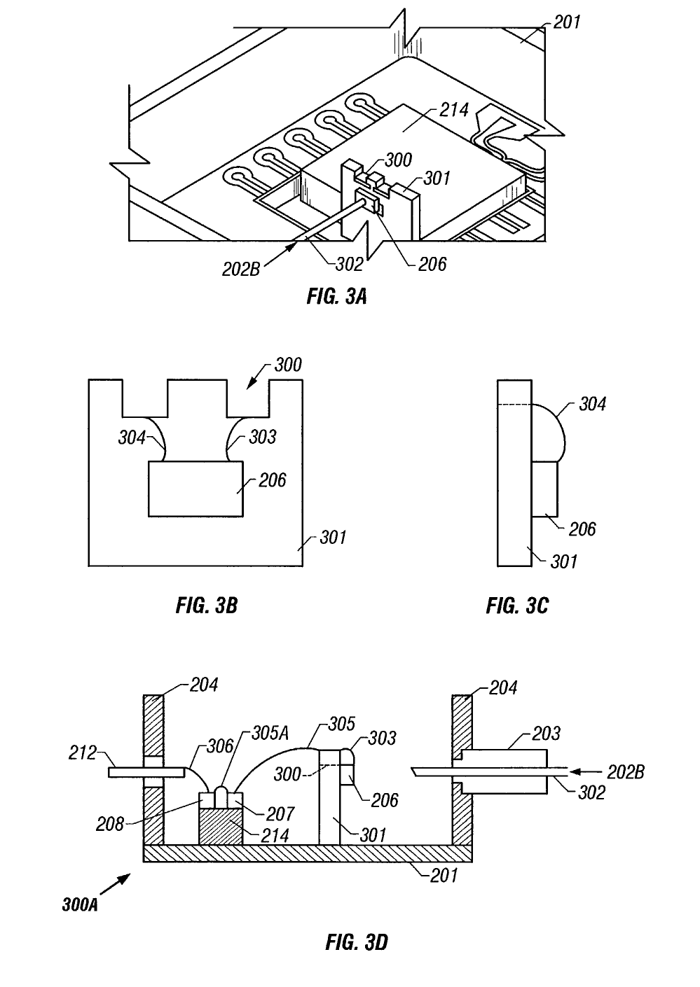

The photodetector subassembly shown in FIGS. 4A, 4B and 4C is used in receiver module 400A illustrated in FIG. 4D. Photodetector 206 is coupled to substrate 301 by wire bond 405. Vias 404 in substrate 301 are coupled to metal tabs 403 that are coupled to transimpedance amplifier 207 by wire bond 406. Due to vias 404, the length of wire bond 405 is reduced compared to conventional packaging systems discussed above (FIG. 2). Transimpedance amplifier 207 is coupled to limiting amplifier 208 by wire bond 305, and limiting amplifier 208 is coupled to optical fiber 212 by wire bond 306.

The exploded view of FIG. 4E includes optical fiber 302 that is aligned with respect to photodetector 206 using spacer 402. Also shown are vias 404, metal tab 403 on substrate 301, which are discussed above.

FIG. 4F is a schematic illustration of a photodetector assembly 400B with optical fiber jacket 401, optical fiber pipe 400, spacer 402, substrate 301, metal tab 403 coupled, as discussed above. Filler opening 407 is used to freeze optical fiber 302 after it is aligned. UV Curing or thermosetting epoxy is dispensed into filler opening 407 after optical fiber 302 alignment and cured. Alternatively, solder could be used to hold optical fiber 302.

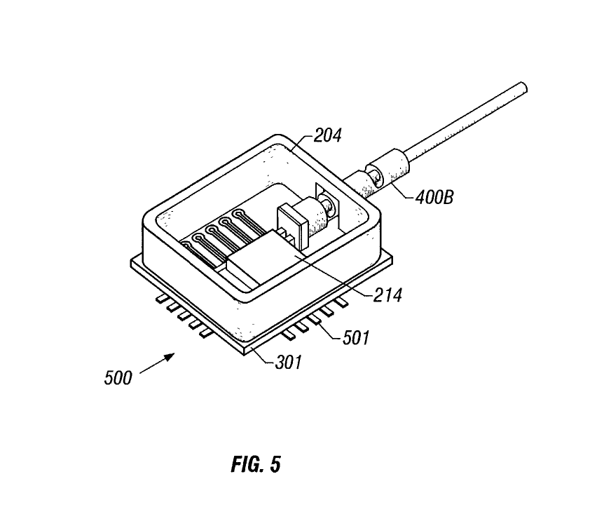

FIG. 5 shows a perspective view of a receiver package 500 that can use the photodetector package 400B and does not require any specific alignment since optical fiber 302 is pre-aligned as shown in FIGS. 4D and 4F, discussed above. Package 500, includes photodetector package 400B with sealing ring 204 and insulating substrate 301. Package 500 includes leads 501 for connecting package 400B to external sources. In package 500, optical fiber 302 does not require any special alignment since it is pre-aligned with respect to the photodetector.

In yet another aspect of the present invention, wire bond length connecting the photodetector to the insulating substrate is reduced which reduces the overall inductance and improves photodetector performance.

While the present invention is described above with respect to what is currently considered its preferred embodiments, it is to be understood that the invention is not limited to that described above. To the contrary, the invention is intended to cover various modifications and equivalent arrangements within the spirit and scope of the appended claims.

What is claimed is:

1. A photodetector packaging system, comprising:
an insulating substrate with a shoulder section; and
a wire bond for coupling the photodetector to the insulating substrate at the shoulder section.

2. The system of claim 1, further comprising:
optical fiber that directs incident light directly to the photodetector.

3. A method for packaging a photodetector, comprising:
mounting the photodetector on a insulating substrate with a shoulder section; and
coupling the photodetector to the insulating substrate shoulder section with a wire bond.

4. The method of claim 3, wherein the photodetector is mounted on the insulating substrate such that the photodetector directly receives incident light from an optical fiber.

5. A system for packaging photodetectors, comprising:
an insulating substrate with conducting vias; and
a wire bond that couples the photodetector to the insulating substrate at the conducting vias.

6. The system of claim 5, further comprising:
conducting tabs coupled to the conducting vias.

7. The system of claim 6, wherein the metal tabs are coupled to a transimpedance amplifier by a wire bond.

8. The system of claim 7, wherein the transimpedance amplifier is coupled to a limiting amplifier by a wire bond.

9. The system of claim 8, wherein the limiting amplifier is coupled to electrical outputs.

10. A method for packaging a photodetector, comprising:
coupling the photodetector to a insulating substrate using conducting vias.

11. The method of claim 10, wherein the photodetector is coupled to the insulating substrate by a wire bond.

12. The method of claim 10, further comprising:
coupling the insulating substrate at the conducting vias to metal tabs.

13. The method of claim 12, further comprising:
coupling the metal tab to a transimpedance amplifier.

14. The method of claim 13, further comprising:
coupling the transimpedance amplifier to a limiting amplifier.
